(19) United States
(12) Patent Application Publication
(10) Pub. No.: US 2025/0318413 A1
(43) Pub. Date: Oct. 9, 2025

(54) LIGHT EMITTING DISPLAY DEVICE AND ELECTRONIC DEVICE INCLUDING THE SAME

(71) Applicant: Samsung Display Co., LTD., Yongin-si (KR)

(72) Inventors: Hyun Eok SHIN, Yongin-si (KR); Ju Hyun LEE, Yongin-si (KR); Yung Bin CHUNG, Yongin-si (KR)

(73) Assignee: Samsung Display Co., LTD., Yongin-si (KR)

(21) Appl. No.: 19/018,803

(22) Filed: Jan. 13, 2025

(30) Foreign Application Priority Data
Apr. 8, 2024 (KR) 10-2024-0047560

(51) Int. Cl. H10K 59/80; H10K 59/122; H10K 59/126; H10K 59/38; H10K 102/00

(52) U.S. Cl. CPC H10K 59/8791; H10K 59/122; H10K 59/126; H10K 59/38; H10K 2102/351

(57) ABSTRACT

A light emitting display device includes a transistor disposed on a substrate, a pixel electrode electrically connected to the transistor, a light emitting layer disposed on the pixel electrode, a common electrode disposed on the light emitting layer, a low reflection layer disposed on the common electrode, and a capping layer disposed on the low reflection layer.

### CROSS-REFERENCE TO RELATED APPLICATION(S)

This application claims priority to and benefits of Korean Patent Application No. 10-2024-0047560 under 35 U.S.C. § 119, filed on Apr. 8, 2024, at the Korean Intellectual Property Office, the entire contents of which are incorporated herein by reference.

### BACKGROUND

### 1. Technical Field

The disclosure relates to a light emitting display device and an electronic device including the same.

### 2. Description of the Related Art

A light emitting display device may include light emitting devices corresponding to pixels, and can display images by controlling the brightness of each light emitting device. Unlike non-emissive display devices such as liquid crystal displays, light emitting display devices do not require a light source such as a backlight, so thickness and weight can be reduced. Additionally, light emitting display devices have characteristics such as high brightness, high contrast ratio, high color reproduction, and high response speed, and can display high-quality images.

Due to these advantages, light emitting display devices are applied to various electronic devices such as mobile devices such as smartphones, tablets, and laptop computers, monitors, and televisions.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

A light emitting display device may include light emitting devices, and the light emitting devices may include a common electrode. Light entering the light emitting display device from outside of the light emitting display device (hereinafter referred to as “external light”) may be reflected by the common electrode, deteriorating display quality.

Embodiments provide a light emitting display device that can reduce external light reflection and an electronic device including the same.

The light emitting display device according to an embodiment may include a transistor disposed on a substrate; a pixel electrode electrically connected to the transistor; a light emitting layer disposed on the pixel electrode; a common electrode disposed on the light emitting layer; a low reflection layer disposed on the common electrode; and a capping layer disposed on the low reflection layer.

The low reflection layer may include at least one of amorphous silicon and silicon carbide.

The low reflection layer may have a thickness of about 10 nm or less.

The low reflection layer may have a thickness in a range of about 2 nm to about 8 nm.

The low reflection layer may have a thickness in a range of about 4 nm to about 8 nm.

The lower surface of the low reflection layer may contact an upper surface of the common electrode.

The upper surface of the low reflection layer may contact the lower surface of the capping layer.

The light emitting display device may further include an encapsulation layer disposed on the capping layer.

The light emitting display device may further include a color filter disposed on the encapsulation layer.

The light emitting display device may further include a pixel defining layer disposed between the pixel electrode and the common electrode, the pixel defining layer having an opening that overlaps the pixel electrode, and a light blocking layer disposed on the encapsulation layer, the light blocking layer having an opening that overlaps the opening of the pixel defining layer.

An electronic device according to an embodiment may include a housing, a cover window disposed on the housing, and a display panel disposed between the housing and the cover window. The display panel may include a transistor disposed on a substrate; a pixel electrode electrically connected to the transistor; a light emitting layer disposed on the pixel electrode; a common electrode disposed on the light emitting layer; a low reflection layer disposed on the common electrode; and a capping layer disposed on the low reflection layer.

The low reflection layer may include at least one of amorphous silicon and silicon carbide.

The low reflection layer may have a thickness of about 10 nm or less.

The low reflection layer may have a thickness in a range of about 2 nm to about 8 nm.

The low reflection layer may have a thickness in a range of about 4 nm to about 8 nm.

A lower surface of the low reflection layer may contact an upper surface of the common electrode.

An upper surface of the low reflection layer may contact a lower surface of the capping layer.

The display panel may further include an encapsulation layer disposed on the capping layer.

The display panel may further include a color filter disposed on the encapsulation layer.

The display panel may further include a pixel defining layer disposed between the pixel electrode and the common electrode and having an opening that overlaps the pixel electrode, and a light blocking layer disposed on the encapsulation layer and having an opening that overlaps the opening of the pixel defining layer.

According to embodiments, a light emitting display device that can reduce external light reflection by a common electrode while minimizing a decrease in light output efficiency and an electronic device including the same can be provided. Additionally, according to the embodiments, there are advantageous effects that can be recognized throughout the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of an electronic device according to an embodiment.

FIG. 2 is a schematic perspective view of a light emitting display device included in an electronic device according to an embodiment.

FIG. 3 is a side view of the light emitting display device of FIG. 2.

FIG. 4 is a schematic plan view schematically showing the connection relationship between components of a light emitting display device according to an embodiment.

FIG. 5 is a schematic plan view illustrating the arrangement of a light emitting region, a color filter, and a light blocking layer in a display area of a light emitting display device according to an embodiment.

FIG. 6 is a schematic cross-sectional view taken along line A-A′ in FIG. 5.

FIG. 7 is a diagram schematically showing reflection characteristics of a light emitting display device according to an embodiment.

FIG. 8 is a graph showing reflectance according to the thickness of a low reflection layer.

FIG. 9 is a graph showing transmittance according to the thickness of a low reflection layer.

FIG. 10, FIG. 11, and FIG. 12 each are a schematic cross-sectional view of a light emitting display device according to an embodiment.

### DETAILED DESCRIPTION OF THE EMBODIMENTS

With reference to the attached drawings, the embodiments will be described in detail so that those skilled in the art can readily implement the disclosure.

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

When a part of a layer, membrane, region, or plate is said to be “above” or “on” another part, this includes not only being “directly on” another component, but also having another component in between. Conversely, when a component is said to be “directly on” another component, it means that there is no other composition in between.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Throughout the specification, a part may further include other components, unless there is a statement to the contrary that it “includes” a certain component.

Throughout the specification, the term “connected” does not only mean that two or more components are directly connected, but it can also include cases where two or more components are indirectly connected through another component, cases where they are physically or electrically connected, as well as cases where different parts, though referred to by different names based on location or function, are essentially integrated and connected to each other.

In the drawings, the symbols “DR1”, “DR2”, and “DR3” are used to indicate directions, where “DR1” is a first direction, “DR2” is a second direction perpendicular to the first direction, and “DR3” is a third direction perpendicular to both the first and second directions.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

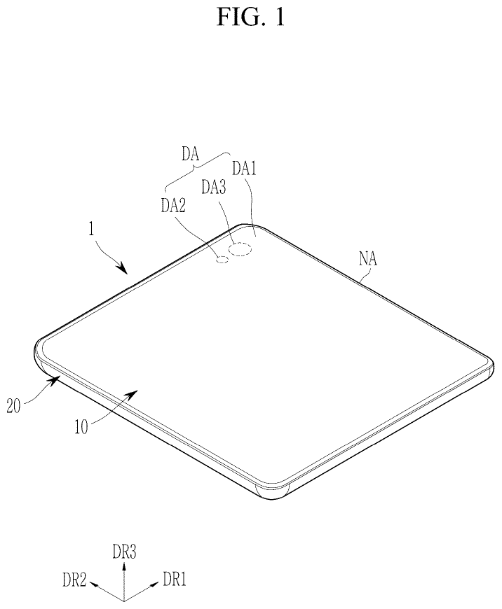

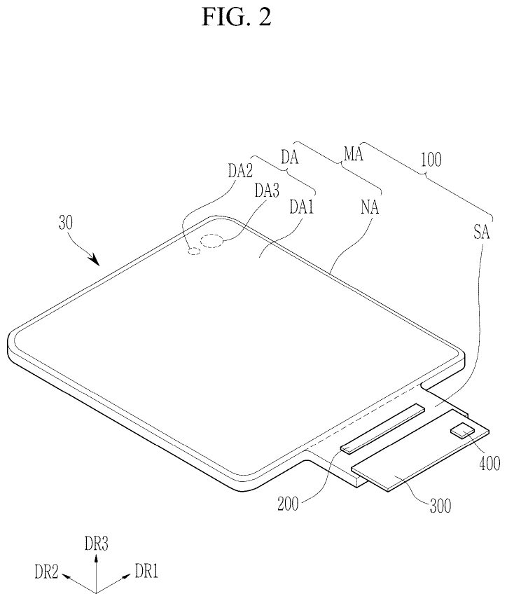

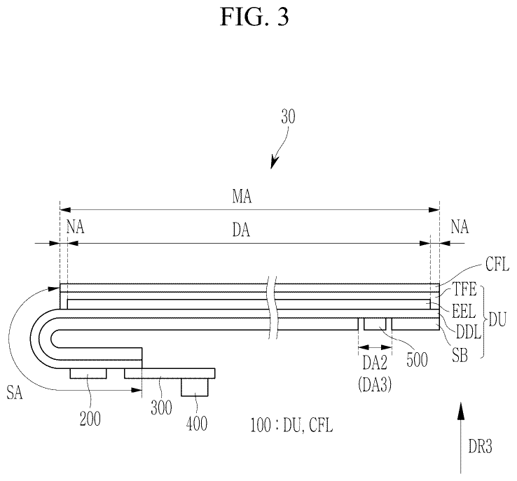

FIG. 1 is a schematic perspective view of an electronic device according to an embodiment, FIG. 2 is a schematic perspective view of a light emitting display device included in the electronic device according to an embodiment, and FIG. 3 is a side view of the light emitting display device of FIG. 2.

Referring to FIGS. 1, 2, and 3, the electronic device 1 moves in a third direction DR3 corresponding to the front in a plane defined by the first direction DR1 and the second direction DR2. It may include a display screen capable of displaying an image. For example, the electronic device 1 may include televisions, laptops, monitors, billboards, mobile phones, smartphones, tablets, electronic watches, smartwatches, watch phones, HMDs (head mounted displays), mobile communication terminals, electronic notepads, e-books, PMPs (portable multimedia players), navigation systems, gaming consoles, digital cameras, camcorders, etc.

The electronic device 1 may include a cover window 10, a housing 20, a display device 30, etc.

The cover window 10 may include an insulating panel. For example, the cover window 10 may be made of glass, plastic, or a combination thereof. The front of the cover window 10 may define the front of the electronic device 1. An area of the cover window 10 corresponding to the display screen may be optically transparent. The cover window 10 is positioned on the display device 30 to protect the display device 30 from external shocks, etc., and to transmit an image displayed by the display device 30.

The housing 20 may be made of a material with relatively high rigidity. For example, the housing 20 may include frames or plates made of glass, plastic, or metal, or a combination thereof. The housing 20 may be combined with the cover window 10, and the combined housing 20 and cover window 10 may form the exterior of the electronic device 1 and provide an internal space for the electronic device 1. For example, the housing 20 may form the back and sides of the electronic device 1, and the cover window 10 may form the front of the electronic device 1. The display device 30 and the like may be positioned in the internal space limited by the cover window 10 and the housing 20, and the display device 30 and the like may be protected from the external environment.

The display device 30 can display images and provide a display screen of the electronic device 1. The display device 30 may be a light emitting display device, such as an organic light emitting display device, an inorganic light emitting display device, or a quantum dot light emitting display device.

The electronic device 1 may have various shapes. For example, the electronic device 1 may have a rectangular shape with rounded corners when viewed from the front, as shown in FIG. 1. The electronic device 1 may have a shape such as a rectangle, square, polygon, circle, or oval.

The electronic device 1 and the display device 30 may include a display area DA and a non-display area NA, respectively. The display area DA and the non-display area NA shown in FIG. 1 may correspond to the display area DA and the non-display area NA of the display device 30 shown in FIGS. 2 and 3. The display area DA is an area where an image is displayed and may correspond to a display screen. The non-display area NA is an area where images are not displayed. The display area DA may occupy most of the area centered on the front of the electronic device 1, and the non-display area NA may surround the display area DA or may be adjacent to the display area DA.

The display area DA may include a first display area DA1, a second display area DA2, and a third display area DA3. The second display area DA2 and the third display area DA3 may be areas where components such as sensors and cameras for adding various functions to the electronic device 1 are placed on the rear side. The second display area DA2 and the third display area DA3 may correspond to a component area. The second display area DA2 and the third display area DA3 may be surrounded by the first display area DA1. In addition to the first display area DA1, the second display area DA2 and the third display area DA3 can display images. The positions and numbers of the second display area DA2 and third display area DA3 may be changed in various ways.

To describe the display device 30 in more detail, the display device 30 can provide a display screen in the electronic device 1. The display device 30 can detect or photograph the front of the electronic device 1. The display device 30 may have a planar shape similar to that of the electronic device 1.

The display device 30 may include a display panel 100, a display driver 200, a printed circuit board 300, and a touch driver 400.

The display panel 100 may include a main area MA and a sub-area SA.

The main area MA may include a display area DA where pixels that display images are arranged (or disposed), and a non-display area NA around the display area DA. The display area DA may include a first display area DA1, a second display area DA2, and a third display area DA3. Components such as sensors or cameras may be placed on the back of the second display areas DA2 and DA3, and the second display area DA2 and the third display area DA3 correspond to the component area.

The display area DA may emit light in the third direction DR3 from light emitting regions corresponding to the light emitting devices. For example, the display panel 100 may include a pixel circuit portion including transistors, signal lines (for example, gate lines, data lines, and voltage lines) connected to the pixel circuit portion, and a light emitting device connected to the pixel circuit portion. The display panel 100 may include a pixel defining layer having an opening that defines a light emitting region of each light-emitting device. The light emitting device may include an organic light emitting diode including an organic light emitting layer, a quantum dot light emitting diode including a quantum dot light emitting layer, an inorganic light emitting diode including an inorganic semiconductor, or a micro light emitting diode.

The non-display area NA may be defined as an edge area of the main area MA of the display panel 100. Circuits and/or signal lines for generating and/or transmitting various signals applied to the display area DA may be disposed in the non-display area NA. For example, in the non-display area NA, a gate driver (not shown) that supplies gate signals to the gate lines and fan-out lines (not shown) connecting the display driver 200 and signal lines in the display area DA are positioned.

The sub-area SA may be an area extending from one side or a side of the main area MA. The sub-area SA may include a flexible area capable of bending, folding, rolling, etc. For example, the sub-area SA may be bent to overlap the main area MA in the thickness direction (third direction DR3). The display driver 200 may be positioned in the sub-area SA, and a pad area may be positioned at the edge.

A printed circuit board 300 may be connected to the pad area. In an embodiment, the sub-area SA may be omitted, and the display driver 200 and the pad area may be placed in the non-display area NA.

The display driver 200 may output signals and voltages for driving the display panel 100. The display driver 200 may supply data voltages to data lines. The display driver 200 may supply a power voltage to power lines and gate control signals to the gate driver. The display driver 200 may be formed as an integrated circuit chip and mounted on the display panel 100. For example, the display driver 200 may be disposed in the sub-area SA, and may overlap the main area MA in the thickness direction (third direction DR3) by bending the sub-area SA. In an embodiment, the display driver 200 may be mounted on the printed circuit board 300.

The printed circuit board 300 may be bonded to the pad area of the display panel 100 using an anisotropic conductive film. Lead wires of the printed circuit board 300 may be electrically connected to pads in the pad area of the display panel 100. The printed circuit board 300 may be flexible.

The touch driver 400 may be mounted on the printed circuit board 300. The touch driver 400 may be electrically connected to a touch sensor included in the electronic device 1. The touch sensor may be provided in the display area DA of the display panel 100. The touch driver 400 may supply a touch driving signal to the sensing electrodes of the touch detecting unit and detect the amount of change in capacitance between the sensing electrodes. For example, the touch driving signal may be a pulse signal with a selectable frequency. The touch driver 400 may calculate whether a touch is touched and touch coordinates based on the amount of change in capacitance between the sensing electrodes. The touch driver 400 may be provided as an integrated circuit chip.

Referring to FIG. 3, the display panel 100 may include a display unit DU and an external light reduction layer CFL. The display unit DU may include a substrate SB, a driving device layer DDL, a light emitting device layer EEL, and an encapsulation layer TFE.

The substrate SB may be a base substrate or a base member. The substrate SB may be a flexible substrate containing a polymer resin such as polyimide, polyamide, or polyethylene terephthalate. The substrate SB may be a rigid substrate made of a material such as glass.

The driving device layer DDL may be positioned on the substrate SB. The driving device layer DDL may include transistors and capacitors that constitute pixel circuit units that output driving currents to light emitting devices. The driving device layer DDL may include gate lines, data lines, power lines, gate control lines, fan-out lines connecting the display driver 200 and the data lines, and lead lines connecting the display driver 200 and the display pads in the pad area. The driving device layer DDL may include transistors and capacitors constituting the gate driver, and gate control lines. The driving device layer DDL may include conductive layers, semiconductor layers, and insulating layers, and may configure and insulate transistors, capacitors, and signal lines by a combination thereof.

The light emitting device layer EEL may be positioned on the driving device layer DDL and may include light emitting devices and corresponding light emitting regions. The light emitting device layer EEL may include a pixel defining layer with an opening defining light emitting regions.

The encapsulation layer TFE (also called “thin film encapsulation layer”) can cover the top and sides of the light emitting device layer EEL and prevent moisture or oxygen from penetrating into the light emitting device layer EEL from the outside. The encapsulation layer TFE may include one or more inorganic layers and one or more organic layers.

The external light reduction layer CFL may be positioned on the encapsulation layer TFE and may include color filters corresponding to each of the light emitting regions. Additionally, the external light reduction layer CFL may include a light blocking layer positioned between adjacent color filters or in an area where adjacent color filters overlap. Light blocking layers may be positioned above, below, and/or to the sides of the color filters. The external light reduction layer CFL may be formed on the encapsulation layer TFE. In the external light reduction layer CFL, color filters may transmit light of a given wavelength and block or absorb light of other wavelengths, and the light blocking layer may absorb external light. Accordingly, the amount of light flowing into the light emitting display device 30 from the outside is reduced, and the amount of light reflected by the light emitting display device 30 is also reduced, thereby reducing disadvantages caused by reflection of external light. Since the external light reduction layer CFL can serve as a given polarizing layer used as a reflection reducing layer, the light emitting display device 30 may not include a polarizing layer, and thus the thickness of the light emitting display device 30 may be reduced, so the light emission efficiency of the light emitting display device 30 can be improved, and power consumption can be reduced. In an embodiment, the external light reduction layer CFL may include a polarizing layer.

The light emitting display device 30 may further include an optical device 500. The optical device 500 may be disposed on the back of the second display area DA2 or the third display area DA3. The optical device 500 may emit or receive light in the infrared, ultraviolet, and/or visible light bands. For example, the optical device 500 may be an optical sensor that detects light incident on the light emitting display device 30, such as a proximity sensor, illuminance sensor, camera sensor, or image sensor.

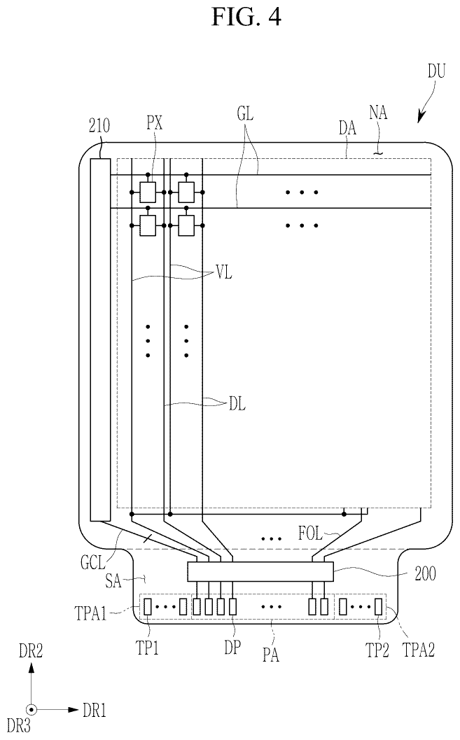

FIG. 4 is a schematic plan view schematically showing the connection relationship between components of a light emitting display device according to an embodiment.

Referring to FIG. 4, the display unit DU of the light emitting display device 30 may include a display area DA and a non-display area NA.

The display area DA may be positioned at the center of the display panel 100. Unit pixels PX, gate lines GL, data lines DL, and power lines VL may be arranged in the display area DA. Each unit pixel PX is the minimum unit that emits light and may include a pixel circuit unit including a transistor and a capacitor, and a light emitting device that receives a driving current from the pixel circuit unit. The unit pixel PX may be connected to a gate line GL, a data line DL, and a power line VL.

The gate lines GL may supply the gate signal applied from the gate driver 210 to the unit pixels PX. The gate lines GL may extend in the first direction DR1 and may be spaced apart from each other in the second direction DR2.

The data lines DL may supply the data voltage applied from the display driver 200 to the unit pixels PX. The data lines DL may extend in the second direction DR2 and may be spaced apart from each other in the first direction DR1.

The power lines VL may supply power voltages applied from the display driver 200 to the unit pixels PX. The power supply voltages may include a high-potential power supply voltage (or driving voltage), a low-potential power supply voltage (or common voltage), an initialization voltage, etc., and these power voltages may be transmitted to the unit pixel PX. The power lines VL may extend in the second direction DR2 and may be spaced apart from each other in the first direction DR1.

The non-display area NA may surround the display area DA or may be adjacent to the display area DA. A gate driver 210, fan-out lines FOL, and gate control lines GCL may be disposed in the non-display area NA. The gate driver 210 may generate gate signals based on gate control signals and supply the gate signals to the gate lines GL in a set order. The fan-out lines FOL may extend from the display driver 200 to the display area DA. The fan-out lines FOL may transfer data voltages output from the display driver 200 to the data lines DL. The gate control lines GCL may extend from the display driver 200 to the gate driver 210. The gate control lines GCL may transmit gate control signals output from the display driver 200 to the gate driver 210.

The light emitting display device 30 may include a sub-area SA. The sub-area SA may include a display driver 200, a pad area PA, a first touch pad area TPA1, and a second touch pad area TPA2.

The display driver 200 may output signals and voltages for driving the display panel 100. The display driver 200 may supply data voltages to the data lines DL through the fan-out lines FOL. Data voltages may be supplied to the unit pixels PX, and the luminance of the unit pixels PX may be controlled. The display driver 200 may supply gate control signals to the gate driver 210 through gate control lines GCL.

The pad area PA, the first touch pad area TPA1, and the second touch pad area TPA2 may be disposed at the edge of the sub-area SA. The display pads DP may be disposed in the pad area PA. The display pads DP may be connected to the graphics system through the printed circuit board 300. The display pads DP are connected to the printed circuit board 300 and can receive digital video data and supply digital video data to the display driver 200. In the first touch pad area TPA1 and the second touch pad area TPA2, touch pads TP1 and TP2 may be placed, and the touch pads TP1 and TP2 are connected to the touch electrodes of the touch sensing part and the touch driver 400 positioned on the printed circuit board 300, enabling them to detect touch.

The pad area PA, the first touch pad area TPA1, and the second touch pad area TPA2 may be electrically connected to the printed circuit board 300 by an anisotropic conductive film or self-assembly anisotropic conductive paste SAP, etc.

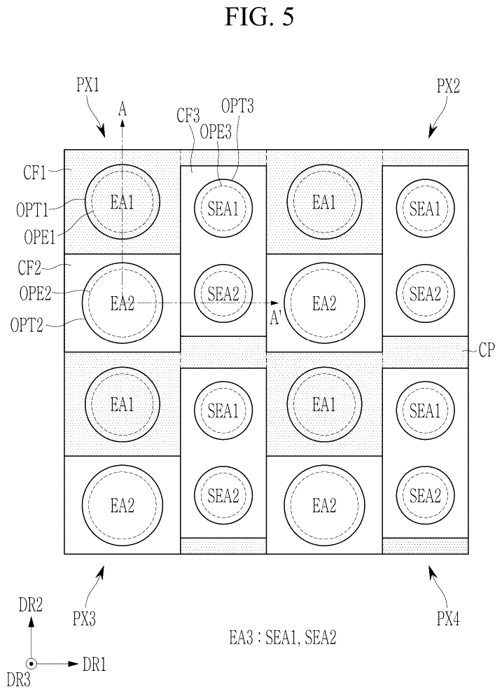

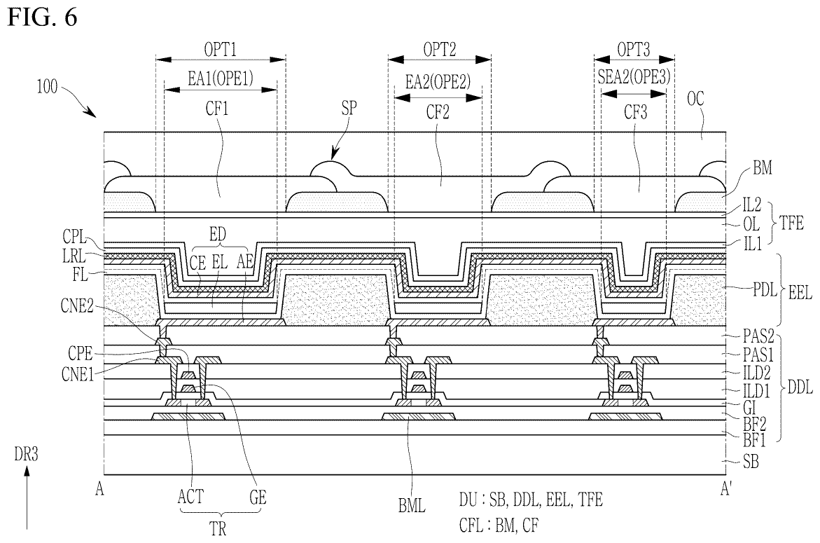

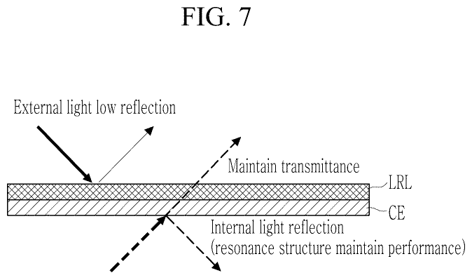

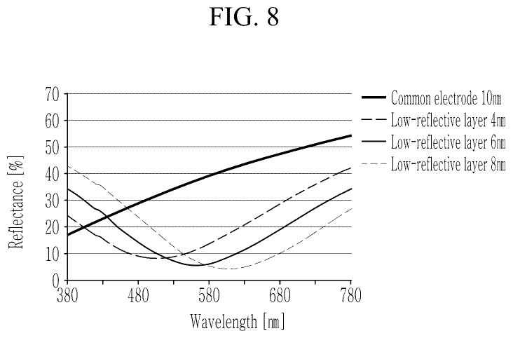

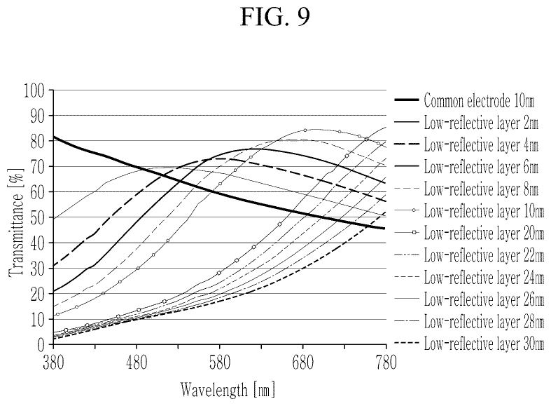

FIG. 5 is a schematic plan view showing the arrangement of a light emitting region, a color filter, and a light blocking layer in a display area of a light emitting display device according to an embodiment, and FIG. 6 is a schematic cross-sectional view taken along line A-A′ in FIG. 5. FIG. 7 is a diagram schematically showing reflection characteristics of a light emitting display device according to an embodiment. FIG. 8 is a graph showing the reflectance according to the thickness of a low reflection layer, and FIG. 9 is a graph showing the transmittance according to the thickness of a low reflection layer.

Referring to FIGS. 5 and 6, the openings OPE1, OPE2, and OPE3 of the pixel defining layer and the openings OPT1, OPT2, and OPT3 of the light blocking layer BM may have a circular planar shape. Because the light reflected by the circular planar shape is reflected without having a given direction, the reflected light can be prevented from being concentrated in a given direction, and the reflected light can be made difficult to see. The color filters CF1, CF2, and CF3 are shown separated by straight lines in FIG. 5.

The light emitting display device 30 may include unit pixels PX1, PX2, PX3, and PX4 arranged in a display area DA and light emitting regions EA1, EA2, and EA3 arranged in each unit pixel PX1, PX2, PX3, and PX4.

The unit pixels PX1, PX2, PX3, and PX4 may include light emitting regions EA1, EA2, and EA3 displaying different colors and may be arranged in the first direction DR1 and the second direction DR2. The first unit pixel PX1 and the second unit pixel PX2 may be adjacent to each other in the first direction DR1, and the first unit pixel PX1 and the third unit pixel PX3 may be adjacent to each other in the second direction DR2. The third unit pixel PX3 and the fourth unit pixel PX4 may be adjacent to each other in the first direction DR1, and the second unit pixel PX2 and the fourth unit pixel PX4 may be adjacent to each other in the second direction DR2. Unlike what is shown, the arrangement of the unit pixels PX1, PX2, PX3, and PX4 may be changed in various ways. For example, the unit pixels PX1, PX2, PX3, and PX4 may be arranged in a PENTILE™ type or a Diamond PENTILE™ type.

The light emitting regions EA1, EA2, and EA3 of each unit pixel PX1, PX2, PX3, and PX4 may include a first light emitting region EA1, a second light emitting region EA2, and a third light emitting region EA3 that emit light of different colors.

The third light emitting region EA3 may include a first sub-light emitting region SEA1 and a second sub-light emitting region SEA2 spaced apart from each other in the second direction DR2. Although the first sub-light emitting region SEA1 and the second sub-light emitting region SEA2 are separated, they may emit light of the same color to form one third light emitting region EA3.

The first, second, and third light emitting regions EA1, EA2, and EA3 may emit light of any one color among red, green, and blue, respectively. For example, the first emitting area EA1 may emit red light, the second light emitting region EA2 may emit green light, and the third light emitting region EA3 may emit blue light. As another example, the first light emitting region EA1 may emit red light, the second light emitting region EA2 may emit blue light, and the third light emitting region EA3 may emit green light.

The first light emitting region EA1, the second light emitting region EA2, the first sub-light emitting region SEA2, and the second sub-light emitting region SEA2 may each have a circular planar shape, and may have an elliptical or approximately circular planar shape. Reflection characteristics can be improved by having the light emitting regions EA1, EA2, and EA3 have a flat shape without any angled portions.

The light emitting regions EA1, EA2, and EA3 in each unit pixel PX1, PX2, PX3, and PX4 may be arranged along the first direction DR1 and the second direction DR2. For example, as shown, the first emitting area EA1 and the second emitting area EA2 may be arranged to be spaced apart in the second direction DR2. The third light emitting region EA3 may be arranged to be spaced apart from the first and second light emitting regions EA1 and EA2 in the first direction DR1. Across the entire display area DA, the first light emitting region EA1 and the second light emitting region EA2 may be alternately arranged along the second direction DR2, and the first sub-light emitting region SEA1 and the second sub-light emitting region SEA2 may be alternately arranged along the second direction DR2. The arrangement of the light emitting regions EA1, EA2, and EA3 may be changed in various ways. For example, the light emitting regions EA1, EA2, and EA3 may be arranged as a PENTILE™ type or a Diamond PENTILE™ type. Color patterns CP may be positioned on both sides of the third light emitting region EA3 in the second direction DR2. The color pattern CP may be a portion of the first color filter CF1 that protrudes in the first direction DR1.

The light emitting regions EA1, EA2, and EA3 may be defined by openings OPE1, OPE2, and OPE3 formed in the pixel defining layer PDL of the light emitting device layer EEL, respectively. For example, the first light emitting region EA1 may be defined by the first opening OPE1, the second light emitting region EA2 may be defined by the second opening OPE2, and the third light emitting region EA3 may be defined by the third opening OPE3. The areas or sizes of the light emitting regions EA1, EA2, and EA3 may be different from each other. In the embodiment of FIG. 5, the area of the first light emitting region EA1 may be larger than the area of the second light emitting region EA2, and the area of the second light emitting region EA2 may be larger than the area of each of the sub-light emitting regions SEA1 and SEA2.

The area of the first sub-light emitting region SEA1 and the area of the second sub-light emitting region SEA2 may be the same. The areas of the light emitting regions EA1, EA2, and EA3 may vary depending on the size of the openings OPE1, OPE2, and OPE3 of the pixel defining layer PDL. The amount of light emitted from the respective light emitting regions EA1, EA2, and EA3 may vary depending on the area of these light emitting regions EA1, EA2, and EA3, and by adjusting the area of these light emitting regions EA1, EA2, and EA3, it is possible to control the color tone of the image displayed on the light emitting display device 30 or electronic device 1. The areas of the light emitting regions EA1, EA2, and EA3 are related to light efficiency, lifespan of the light emitting device ED, etc., and may have a trade-off relationship with reflection by external light. The areas of the light emitting regions EA1, EA2, and EA3 may be adjusted considering the aforementioned matters. The light emitting display device 30 may be designed so that the area of the light emitting regions EA1, EA2, and EA3 or the area of the openings OPE1, OPE2, and OPE3 in the pixel defining layer PDL allows the reflected external light to be perceived as a mixed white light.

The light emitting display device 30 may include color filters CF1, CF2, and CF3 disposed on the light emitting regions EA1, EA2, and EA3. The color filters CF1, CF2, and CF3 may be arranged to correspond to the light emitting regions EA1, EA2, and EA3 or the openings OPE1, OPE2, and OPE3. The color filters CF1, CF2, and CF3 may include a first color filter CF1 overlapping the first light emitting region EA1, a second color filter CF2 overlapping the second light emitting region EA2, and a third color filter CF3 overlapping the third light emitting region EA3. Each color filter CF1, CF2, and CF3 may have an area larger than the openings OPE1, OPE2, and OPE3 of the pixel defining layer PDL. The color filters CF1, CF2, and CF3 may contain colorants such as dyes or pigments that absorb light of wavelengths other than given wavelengths, and may be arranged to correspond to the colors of light emitted from the emitting regions EA1, EA2, and EA3. For example, the first color filter CF1 may be a red color filter that only transmits red light, the second color filter CF2 may be a green color filter that only transmits green light, and the third color filter CF3 may be a blue color filter that only transmits blue light.

Similar to the arrangement of the light emitting regions EA1, EA2, and EA3, the color filters CF1, CF2, and CF3 may be arranged in the first direction DR1 and the second direction DR2. For example, the first color filter CF1 and the second color filter CF2 may be arranged adjacent to each other in the second direction DR2, and the third color filter CF3 may be disposed adjacent to the first and second color filters CF1 and CF2 and may be placed adjacent to each other in the first direction DR1. In FIG. 5, the boundaries of adjacent color filters CF1, CF2, and CF3 are shown as straight lines, however, as shown in FIG. 6, the edge parts of the adjacent color filters CF1, CF2, and CF3 may overlap each other to form an overlapping portion SP. Referring to FIG. 6, the overlapping portion SP of the color filters CF1, CF2, and CF3 is formed relatively high, so that there may be a step difference from the non-overlapping portions of the color filters CF1, CF2, and CF3. As the color filters CF1, CF2, and CF3 are arranged to overlap, the intensity of reflected light caused by external light can be reduced. The color tone of reflected light due to external light may be controlled by adjusting the arrangement, shape, and area of the color filters CF1, CF2, and CF3.

The light emitting display device 30 may include a color pattern CP that protrudes from the first color filter CF1 in the first direction DR1 and contacts the third color filter CF3 in the second direction DR2. The color pattern CP may include a same material as the first color filter CF1 and may be integrated with the first color filter CF1. The color pattern CP may include a same material as the first color filter CF1 and be disposed in each unit pixel PX1, PX2, PX3, and PX4 in consideration of the color of the light reflected from the light emitting display device 30. The color pattern CP may be arranged adjacent to the third color filter CF3 in the second direction DR2, but the position of the color pattern CP for each unit pixel PX1, PX2, PX3, and PX4 may be different. For example, in the first unit pixel PX1 and the fourth unit pixel PX4, the color pattern CP may be placed on the upper side, which is one side or a side of the second direction DR2 of the third color filter CF3, and in the second unit pixel PX2 and the third unit pixel PX3, the color pattern CP may be placed on the lower side, which is the other side or another side of the second direction DR2 of the third color filter CF3. The color pattern CP may be arranged across two unit pixels of PX1, PX2, PX3, and PX4 adjacent to each other in the second direction DR2. The color patterns CP may be arranged to be spaced apart in the second direction DR2 throughout the display area DA.

The areas of the light emitting regions EA1, EA2, and EA3 may be different from each other, and the areas of the color filters CF1, CF2, and CF3 may also be different. The light emitting regions EA1, EA2, and EA3 may have areas according to a given ratio, and the color filters CF1, CF2, and CF3 may similarly have areas according to a given ratio. However, the area ratio between the light emitting regions EA1, EA2, and EA3 and the area ratio between the color filters CF1, CF2, and CF3 may be different. In case that external light is reflected by the light emitting display device 30, the relative area ratio of the color filters CF1, CF2, and CF3 may affect the color of the reflected external light. The light emitting display device 30 may include color filters CF1, CF2, and CF3 that have given proportions of area, and a color pattern CP that contains a same material as the red color filter, so that the color of external light may be comfortable to the user's eyes. The arrangement of the color filters CF1, CF2, and CF3 may be changed in various ways. For example, the color filters CF1, CF2, and CF3 may be arranged as a PENTILE™ type or a Diamond PENTILE™ type.

The light emitting display device 30 may include a light blocking layer BM disposed between the light emitting regions EA1, EA2, and EA3 and the color filters CF1, CF2, and CF3. The light blocking layer BM may include openings OPT1, OPT2, and OPT3. The openings OPT1, OPT2, and OPT3 of the light blocking layer BM may overlap the openings OPE1, OPE2, and OPE3 of the pixel defining layer PDL corresponding to the light emitting regions EA1, EA2, and EA3, and may form a light emitting region where light emitted from the light emitting regions EA1, EA2, and EA3 is emitted. The color filters CF1, CF2, and CF3 may each have a larger area than the corresponding openings OPT1, OPT2, and OPT3 of the light blocking layer BM and the corresponding openings OPE1, OPE2, and OPE3 of the pixel defining layer PDL, and may completely cover the corresponding light emitting regions.

Referring to FIG. 6, to describe the cross-sectional structure of the light emitting display device 30 in more detail, the display panel 100 of the light emitting display device 30 may include a display unit DU and an external light reduction layer CFL. The display unit DU may include a substrate SB, a driving device layer DDL, a light emitting device layer EEL, and an encapsulation layer TFE. The external light reduction layer CFL disposed on the encapsulation layer TFE may include a light blocking layer BM, color filters CF1, CF2, and CF3, and an overcoat layer OC.

The substrate SB may be a flexible or rigid substrate. The substrate SB may include one or more polymer layers and one or more barrier layers. The barrier layer may include inorganic insulating materials such as a silicon nitride SiNₓ, a silicon oxide SiOₓ, and a silicon oxynitride SiOₓN_{y}, and can prevent the penetration of moisture, oxygen, etc.

The driving device layer DDL may include a first buffer layer BF1, a lower metal layer BML, a second buffer layer BF2, a transistor TR, a gate insulation layer GI, a first interlayer insulation layer ILD1, a capacitor electrode CPE, a second interlayer insulation layer ILD2, a first connection electrode CNE1, a first protective layer PAS1, a second connection electrode CNE2, a second protective layer PAS2, etc.

The first buffer layer BF1 may be positioned on the substrate SB, the lower metal layer BML may be positioned on the first buffer layer BF1, and the second buffer layer BF2 may cover the lower metal layer BML.

The transistor TR may be positioned on the second buffer layer BF2. The transistor TR may be a driving transistor or a switching transistor of the pixel circuit unit. The transistor TR may include a semiconductor layer ACT and a gate electrode GE.

The semiconductor layer ACT may be positioned on the second buffer layer BF2. The semiconductor layer ACT may overlap the lower metal layer BML. The semiconductor layer ACT may include a first region, a second region, and a channel region between these regions. The semiconductor layer ACT may include a semiconductor material such as an oxide semiconductor, amorphous silicon, or polycrystalline silicon. For example, the semiconductor layer ACT may include low-temperature polycrystalline silicon LTPS or an oxide semiconductor material containing at least one of zinc (Zn), indium (In), gallium (Ga), and tin (Sn). For example, the semiconductor layer ACT may include Indium-Gallium-Zinc Oxide IGZO. The first region and the second region may be regions in the semiconductor layer ACT where a semiconductor material is conductive.

The gate electrode GE may be positioned on the gate insulating layer GI and may overlap the channel region of the semiconductor layer ACT.

The gate insulating layer GI may cover the semiconductor layer ACT and insulate the semiconductor layer ACT and the gate electrode GE. The first interlayer insulating layer ILD1 may cover the gate electrode GE.

The capacitor electrode CPE may be positioned on the first interlayer insulating layer ILD1. The capacitor electrode CPE may overlap the gate electrode GE. The capacitor electrode CPE and the gate electrode GE may form a capacitor. The second interlayer insulating layer ILD2 may cover the capacitor electrode CPE.

The lower metal layer BML, gate electrode GE, and capacitor electrode CPE may each include molybdenum (Mo), aluminum (Al), copper (Cu), titanium (Ti), etc., and may be a single layer or a multilayer. The first buffer layer BF1, the second buffer layer BF2, the gate insulating layer GI, the first interlayer insulating layer ILD1, and the second interlayer insulating layer ILD2 may each include inorganic insulating materials such as a silicon nitride, a silicon oxide, and a silicon oxynitride, and may be single-layered or multi-layered.

The first connection electrode CNE1 may be positioned above the second interlayer insulating layer ILD2, and may be connected to the first region of the semiconductor layer ACT through a contact hole formed in the gate insulation layer GI, the first interlayer insulating layer ILD1, and the second interlayer insulating layer ILD2. The first protective layer PAS1 may cover the first connection electrode CNE1.

The second connection electrode CNE2 may be positioned on the first protective layer PAS1 and may be connected to the first connection electrode CNE1 through a contact hole formed in the first protective layer PAS1. The second protective layer PAS2 may cover the second connection electrode CNE2.

The first connection electrode CNE1 and the second connection electrode CNE2 may each include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may be a single layer or multiple layers.

The first protective layer PAS1 and the second protective layer PAS2 may each include organic insulating materials such as general-purpose polymers like poly(methyl methacrylate), polystyrene, polymer derivatives containing phenolic groups, acrylic polymers, imide polymers (for example, polyimide), and siloxane polymers.

The light emitting device layer EEL may be positioned on the driving device layer DDL. The light emitting device layer EEL may include a light emitting device ED, a pixel defining layer PDL, a low reflection layer LRL, and a capping layer CPL. The light emitting device ED may include a pixel electrode AE, a light emitting layer EL, and a common electrode CE. The light emitting device ED may further include a functional layer FL including at least one of a hole injection layer, a hole transport layer, an electron injection layer, and an electron transport layer. The functional layer FL may include a portion positioned between the pixel electrode AE and the light emitting layer EL and a portion positioned between the light emitting layer EL and the common electrode CE.

The pixel electrode AE may be positioned on the second protective layer PAS2 and may be connected to the second connection electrode CNE2 through a contact hole formed in the second protective layer PAS2. Accordingly, the pixel electrode AE may be electrically connected to the first region of the semiconductor layer ACT of the transistor TR, and may receive a driving current through the transistor TR. The pixel electrode AE may be formed of a reflective conductive material or a semi-transparent conductive material, or may be formed of a transparent conductive material. The pixel electrode AE may include a transparent conductive material such as indium tin oxide ITO or indium zinc oxide IZO. The pixel electrode AE may include a metal or metal alloy such as lithium (Li), calcium (Ca), aluminum (Al), silver (Ag), magnesium (Mg), or gold (Au). The pixel electrode AE may be multi-layered, for example, may have a triple-layer structure such as ITO/silver (ITO/Ag).

The light emitting layer EL may be positioned on the pixel electrode AE. For example, the light emitting layer EL may be an organic light emitting layer made of an organic material. The functional layer FL positioned between the light emitting layer EL and the pixel electrode AE may include at least one of a hole injection layer and a hole transport layer, and the functional layer FL positioned between the light emitting layer EL and the common electrode CE may include at least one of an electron transport layer and an electron injection layer.

The common electrode CE may be positioned on the light emitting layer EL. The common electrode CE may form a light emitting device ED such as an organic light emitting diode or an inorganic light emitting diode together with the pixel electrode AE and the light emitting layer EL. The pixel electrode AE may be an anode of the light emitting device ED, and the common electrode CE may be a cathode of the light emitting device ED. The common electrode CE may be made to have light transmittance by forming a thin layer of metals or metal alloys with low work functions such as calcium (Ca), barium (Ba), magnesium (Mg), aluminum (Al), and silver (Ag). For example, the common electrode CE may include magnesium-silver (Mg—Ag). The common electrode CE may include a transparent conductive oxide such as indium tin oxide ITO or indium zinc oxide IZO. A low-potential power supply voltage (or common voltage) may be applied to the common electrode CE.

The pixel defining layer PDL may be positioned on the second protective layer PAS2 and may cover an edge of the pixel electrode AE. The pixel defining layer PDL may include openings OPE1, OPE2, and OPE3 that overlap the pixel electrode AE. As described above, the openings OPE1, OPE2, and OPE3 of the pixel defining layer PDL may define the first to third light emitting regions EA1, EA2, and EA3, and their areas or sizes are different from each other. The pixel defining layer PDL may be a black pixel defining layer containing a colored pigment such as a black pigment, a blue pigment, etc. For example, the pixel defining layer PDL may include a polyimide binder and a pigment mixed with red, green, and blue. For example, the pixel defining layer PDL may include a cardo binder resin and a mixture of a lactam black pigment and a blue pigment. The pixel defining layer PDL may include carbon black. The black pixel defining layer can improve contrast ratio and prevent reflection by the metal layer positioned below.

The low reflection layer LRL may be positioned on the common electrode CE. The low reflection layer LRL may include a material that can reduce external light reflection by the common electrode CE while transmitting light emitted from the light emitting device layer EEL. The low reflection layer LRL may include a semiconductor material such as amorphous silicon (a-Si) or silicon carbide (SiC). The low reflection layer LRL may have a thickness of about 10 nm or less. For example, the low reflection layer LRL may have a thickness in a range of about 1 nm to about 10 nm, in a range of about 2 nm to about 10 nm, in a range of about 4 nm to about 10 nm, in a range of about 6 nm to about 10 nm, in a range of about 2 nm to about 8 nm, in a range of about 4 nm to about 8 nm, or in a range of about 6 nm to about 8 nm. If the low reflection layer LRL is thicker than a selectable thickness, the reflectance by the common electrode CM and the low reflection layer LRL may increase. If the low reflection layer LRL is thicker than a selectable thickness, the transmittance of light emitted from the light emitting device layer EEL may decrease. If the low reflection layer LRL is thinner than a selectable thickness, the effect of reducing external light by the low reflection layer LRL may be minimal.

The low reflection layer LRL may be formed entirely on the common electrode CE. For example, the low reflection layer LRL may be formed by a deposition method such as chemical vapor deposition (CVD) using a mask that may be used in case that forming the common electrode CE. Therefore, the low reflection layer LRL may be formed without using an additional mask or patterning process. The lower surface of the low reflection layer LRL may be in contact with the upper surface of the common electrode CE. The low reflection layer LRL may cover the entire common electrode CE. The edge of the low reflection layer LRL may coincide with the edge of the common electrode CE. The upper surface of the low reflection layer LRL may be in contact with the capping layer CPL.

FIG. 7 briefly shows only the common electrode CE and the low reflection layer LRL among the components of the display device. The low reflection layer LRL formed of a selectable material and thickness is positioned on the common electrode CE and can absorb a portion of external light. Accordingly, external light reflection by the common electrode CE can be reduced, and the display quality of light emitting displays and electronic devices can be improved. This effect of reducing external light reflection can be achieved without substantially reducing the transmittance of light emitted from the light emitting device ED. Since the low reflection layer LRL is positioned on the common electrode CE, the performance of the resonance structure in which a part of the light emitted from the light emitting layer EL of the light emitting device ED is reflected by the common electrode CE can be maintained. For example, since the low reflection layer LRL is positioned on the common electrode CE, it may not affect the resonance structure implemented by the common electrode CE and the pixel electrode AE.

Referring to FIG. 8, it shows the reflectance in the visible light range of a common electrode CE with a thickness of about 10 nm containing Ag—Mg, and the reflectance in the visible light range according to the thickness of the low reflection layer LRL containing amorphous silicon applied on such common electrode CE.

Table 1 below shows the reflectance at a wavelength of about 550 nm according to the thickness of the low reflection layer LRL that may include amorphous silicon, applied on a common electrode CE with a thickness of about 10 nm.

TABLE 1

| | | | | | | | | | |
|---|---|---|---|---|---|---|---|---|---|
| Low reflection layer | 0 | 2 | 4 | 6 | 8 | 10 | 26 | 28 | 30 |
| thickness (nm) | | | | | | | | | |
| Reflectance | 36 | 22 | 11 | 6 | 8 | 25 | 64 | 66 | 67 |
| (% at 550 nm) | | | | | | | | | |

A common electrode CE is included but does not include the low reflection layer LRL (for example, in case that the thickness of the low reflection layer is about 0 nm), the reflectance increased as the wavelength increased, and by way of example, the reflectance was in a range of about 36% at about 550 nm. In case that a low reflection layer LRL was formed on the common electrode CE, the reflectance decreased and increased as the wavelength increased. By way of example, in the green wavelength region, where the human eye is most sensitive, the reflectance was significantly reduced compared to the case without a low reflection layer LRL. For example, in case that the thickness of the low reflection layer LRL was about 10 nm or less, the about 550 nm reflectance was found to be less than about 25%, which improved the 550 nm reflectance by more than about 30% compared to the case where the low reflection layer LRL was not formed. In the range of the low reflection layer LRL thickness in a range of about of 2 nm to about 8 nm, the 550 nm reflectance was improved in a range of about 39% to about 83% compared to the case where the low reflection layer LRL was not formed. Referring to FIG. 9, it shows the transmission in the visible light spectrum of a common electrode CE with a thickness of about 10 nm containing Ag—Mg, and the transmission in the visible light spectrum according to the thickness of a low reflection layer LRL that may include amorphous silicon applied on top of this common electrode CE. Table 2 below shows the reflectance and average visible light transmittance at a wavelength of about 550 nm according to the thickness of the low reflection layer LRL containing amorphous silicon applied on an about 10 nm thick common electrode CE.

TABLE 2

| | | | | | | | | | |
|---|---|---|---|---|---|---|---|---|---|
| Low | 0 | 2 | 4 | 6 | 8 | 10 | 26 | 28 | 30 |
| reflection layer | | | | | | | | | |
| thickness (nm) | | | | | | | | | |
| Transmittance | 62 | 68 | 72 | 69 | 63 | 54 | 17 | 16 | 15 |
| (% at 550 nm) | | | | | | | | | |
| Transmittance | 57.4 | 58.5 | 58.2 | 57.1 | 55.0 | 52.0 | | | |
| (%, visible light | | | | | | | | | |
| average) | | | | | | | | | |

In case that including a common electrode CE and not including a low reflection layer LRL (for example, in case that the thickness of the low reflection layer is about 0 nm), the transmittance decreased as the wavelength increased, and especially at about 550 nm, transmittance of about 62% appeared. In case that a low reflection layer LRL with a thickness of about 10 nm or less was formed on the common electrode CE, the transmittance increased and decreased as the wavelength increased. In the green wavelength region, where the human eye is most sensitive, the transmittance was similar or higher than in case that the low reflection layer LRL was not included. For example, in case that a low reflection layer LRL with a thickness in a range of about 2 nm to about 8 nm was applied, the 550 nm transmittance was found to be in a range of about 63% to about 72%. The average visible light transmittance was shown to be over about 52.0% in case that a low reflection layer LRL with a thickness of less than about 10 nm was applied, and it exceeded the case without a low reflection layer LRL in case that a low-reflection layer LRL with a thickness in a range of about 2 nm to about 4 nm was applied. In case that a low reflection layer LRL with a thickness of 20 nm or more was formed on the common electrode CE, the transmittance increased as the wavelength increased, but the transmittance was very low in the low wavelength region, at about 23% or less at about 550 nm.

Thus, if the thickness of the low reflection layer LRL is about 10 nm or less, the transmission loss was not significant compared to in case that the low reflection layer LRL was not formed, and in case that a low reflection layer LRL with a thickness in a range of about 2 to about 8 nm was formed, the transmittance at about 550 nm actually increased. Therefore, in case that applying a low reflection layer LRL with a thickness of about 10 nm or less on the common electrode CE, external light reflection is effectively reduced, while the light loss (lower transmittance of light emitted from the light emitting device ED) due to the low reflection layer LRL is minimized.

The capping layer CPL can improve the light emission efficiency of the light emitting device ED based on the principle of constructive interference. The capping layer CPL may include a material having a refractive index (at about 589 nm) of about 1.6 or more. The thickness of the capping layer CPL may be in a range of about 1 nm to about 200 nm, such as in a range of about 5 nm to about 150 nm, or in a range of about 10 nm to about 100 nm. The capping layer CPL may be an organic capping layer containing an organic material, an inorganic capping layer containing an inorganic material, or a composite capping layer including an organic material and an inorganic material. For example, the capping layer CPL may include carboxylic compounds, heterocyclic compounds, amine-containing compounds, porphine derivatives, phthalocyanine derivatives, naphthalocyanine derivatives, alkali metal complexes, alkaline earth metal complexes, or any combination thereof. Carbocyclic compounds, heterocyclic compounds, and amine group-containing compounds may optionally be substituted with substituents including O, N, S, Se, Si, F, Cl, Br, I, or any combination thereof.

The encapsulation layer TFE may be positioned on the light emitting device layer EEL and may cover the light emitting devices ED. The encapsulation layer TFE can seal the light emitting device layer EEL and prevent moisture or oxygen from penetrating from the outside. The encapsulation layer TFE may be a thin film encapsulation layer including one or more inorganic layers and one or more organic layers. For example, the encapsulation layer TFE may have a triple-layer structure of a first inorganic layer IL1, an organic layer OL, and a second inorganic layer IL2. The first inorganic layer IL1 may cover the common electrode CE and prevent moisture or oxygen from penetrating into the light emitting device ED. The organic layer OL can cover surface irregularities of the first inorganic layer IL1 or particles existing on the first inorganic layer IL1, and can block the influence of the surface condition of the first inorganic layer IL1 on the configurations formed on the organic layer OL. The organic layer OL can relieve stress between contacting layers. The second inorganic layer IL2 may cover the organic layer OL. The second inorganic layer IL2 can prevent moisture, etc. from being released from the organic layer OL. The first inorganic layer IL1 and the second inorganic layer IL2 may include an inorganic material such as a silicon oxide, a silicon nitride, a silicon oxynitride, an aluminum oxide, a titanium oxide, a tantalum oxide, a hafnium oxide, and a zinc oxide. The organic layer OL may include organic materials such as acrylic resin, epoxy resin, polyimide, and polyethylene.

The external light reduction layer CFL positioned on the encapsulation layer TFE may include a light blocking layer BM, color filters CF1, CF2, and CF3, and an overcoat layer OC.

The light blocking layer BM may be positioned on the encapsulation layer TFE. The light blocking layer BM may include openings OPT1, OPT2, and OPT3 that overlap the light emitting regions EA1, EA2, and EA3. The area or size of each opening OPT1, OPT2, and OPT3 may be larger than the area or size of the corresponding openings OPE1, OPE2, and OPE3 of the pixel defining layer PDL. As the openings OPT1, OPT2, and OPT3 of the light blocking layer BM are formed larger than the openings OPE1, OPE2, and OPE3 of the pixel defining layer PDL, and the light emitted from the emitting regions EA1, EA2, and EA3 may be emitted not only in the front direction of the light emitting display device 30 but also in the lateral direction. The light blocking layer BM may include a light absorbing material. For example, the light blocking layer BM may include an inorganic black pigment or an organic black pigment. The inorganic black pigment may be carbon black, and the organic black pigment may include lactam black, perylene black, and/or aniline black. The light blocking layer BM can improve the color reproduction rate of the light emitting display device 30 by preventing visible light from invading and mixing colors between the first to third light emitting regions EA1, EA2, and EA3.

Color filters CF1, CF2, and CF3 may be positioned on the light blocking layer BM. The color filters CF1, CF2, and CF3 may be arranged to correspond to the light emitting regions EA1, EA2, and EA3. For example, the first color filter CF1 may overlap the first opening OPE1 of the pixel defining layer PDL and the first opening OPT1 of the light blocking layer BM, the second color filter CF2 may overlap the second opening OPE2 of the pixel defining layer PDL and the second opening OPT2 of the light blocking layer BM, and the third color filter CF3 may overlap the third opening OPE3 of the pixel defining layer PDL and the third opening OPT3 of the light blocking layer BM. Each color filter CF1, CF2, and CF3 may be arranged to have a larger area than the corresponding opening OPT1, OPT2, and OPT3 of the light blocking layer BM, and parts of each color filter CF1, CF2, and CF3 may overlap the light blocking layer BM. The overlapping portion SP, where adjacent color filters CF1, CF2, and CF3 overlap, may be positioned on the light blocking layer BM.

The overcoat layer OC may cover the color filters CF1, CF2, and CF3 and may flatten the upper surface of the display panel 100. The overcoat layer OC may include a colorless, light-transmitting organic material such as acrylic resin. The refractive index of the overcoat layer OC may be different from the refractive index of the color filters CF1, CF2, and CF3. The refractive index of the overcoat layer OC may be smaller or larger than the refractive index of the color filters CF1, CF2, and CF3. Accordingly, light may be refracted at the boundary between the overcoat layer OC and the color filters CF1, CF2, and CF3.

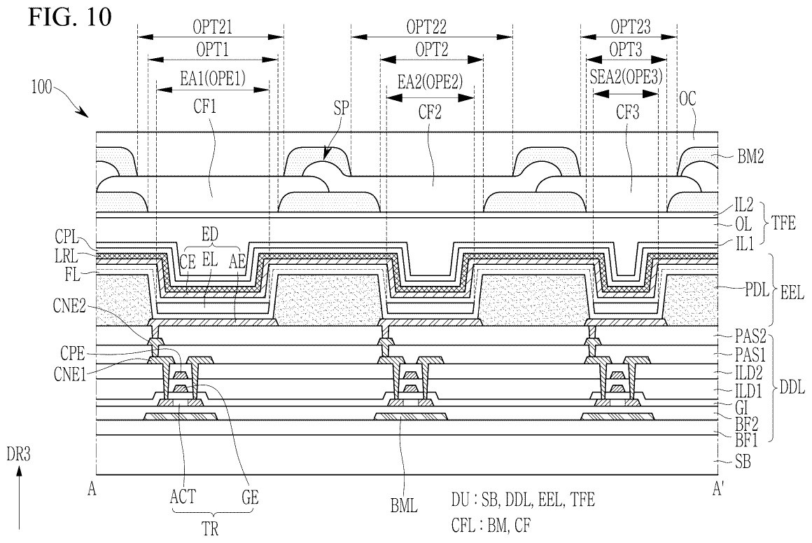

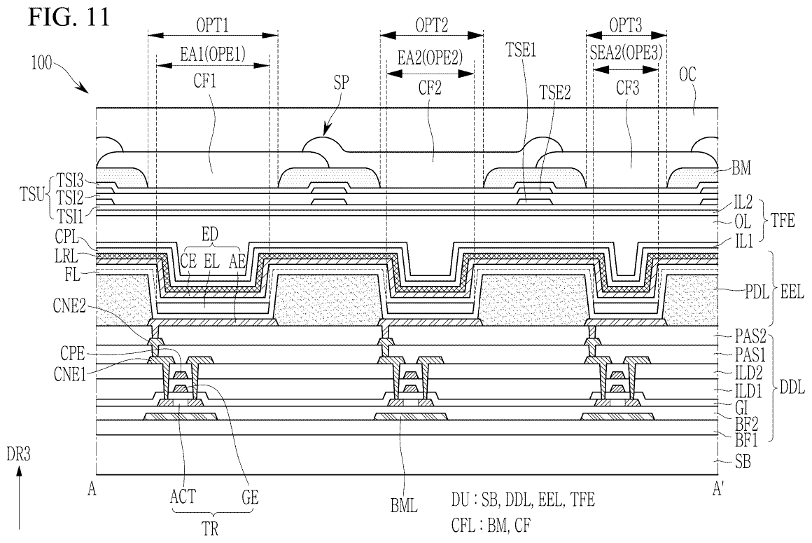

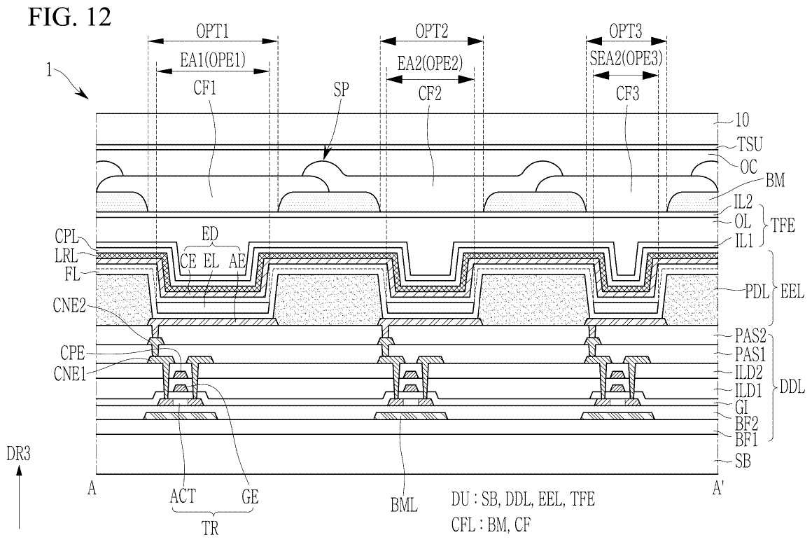

FIG. 10, FIG. 11, and FIG. 12 each are a schematic cross-sectional view of a light emitting display device according to an embodiment.

Referring to FIG. 10, the cross-section shown may correspond to the cross-section taken along line A-A′in FIG. 5. In the embodiment of FIG. 10, compared to the embodiment of FIG. 6, the display panel 100 further may include an upper light blocking layer BM2 positioned above the overlapping portion SP of the color filters CF1, CF2, and CF3. The upper light blocking layer BM2 covers the overlapping portion SP of the color filters CF1, CF2, and CF3 to reduce the scattering and reflection of external light in the overlapping portion SP, thereby reducing the visibility of reflection diffraction. Openings OPT21, OPT22, and OPT23 may be formed in the upper light blocking layer BM2. The openings OPT21, OPT22, and OPT23 of the upper light blocking layer BM2 may overlap the openings OPT1, OPT2, and OPT3 of the light blocking layer BM and the openings OPE1, OPE2, and OPE3 of the pixel defining layer PDL, and may form a light emitting region where light emitted from the emitting regions EA1, EA2, and EA3 is projected. The openings OPT21, OPT22, and OPT23 of the upper light blocking layer BM2 may have a larger area than the corresponding openings OPT1, OPT2, and OPT3 of the light blocking layer BM, and when viewed in a plan view, the corresponding openings OPT1, OPT2, and OPT3 of the light blocking layer BM may be positioned in the openings OPT21, OPT22, and OPT23 of the upper light blocking layer BM2.

The upper light blocking layer BM2 may include a light absorbing material. For example, the upper light blocking layer BM2 may include an inorganic black pigment such as carbon black, or an organic black pigment such as lactam black, perylene black, or aniline black. The upper light blocking layer BM2 can improve the color gamut of the light emitting display device 30 by preventing visible light from invading and mixing colors between the first to third light emitting regions EA1, EA2, and EA3.

Referring to FIG. 11, the display panel 100 may include a touch detecting unit TSU that detects a touch. The touch detecting unit TSU may be positioned between the encapsulation layer TFE and the external light reduction layer CFL. The structure other than the touch detecting unit TSU may be the same as the embodiment of FIG. 6.

The touch detecting unit TSU is positioned between the encapsulation layer TFE and the light blocking layer BM, and may include sensing electrodes TSE1 and TSE2 that overlap the light blocking layer BM and insulating layers TSI1, TSI2, and TSI3 positioned on at least one side or a side of the sensing electrodes TSE1 and TSE2. The sensing electrodes TSE1 and TSE2 may be insulated with an insulating layer TSI2 therebetween, and some may be electrically connected through contact holes formed in the insulating layer TSI2. The light blocking layer BM may overlap the sensing electrodes TSE1 and TSE2 and prevent external light from being reflected by the sensing electrodes TSE1 and TSE2. The sensing electrodes TSE1 and TSE2 may be electrically connected to the touch driver 400 of the light emitting display device 30 shown in FIG. 2. The touch driver 400 may supply a touch driving signal to the sensing electrodes TSE1 and TSE2 and detect a change in capacitance between the sensing electrodes TSE1 and TSE2. The sensing electrodes TSE1 and TSE2 may include metals or metal alloys such as aluminum (Al), copper (Cu), silver (Ag), gold (Au), molybdenum (Mo), titanium (Ti), and tantalum (Ta), and may be either a single layer or multiple layers. The insulating layers TSI1, TSI2, and TSI3 may include an inorganic insulating material and/or an organic insulating material.

Referring to FIG. 12, the cover window 10 may be positioned on the overcoat layer OC of the display panel 100. The cover window 10 can protect the display panel 100 from external impacts while covering the display panel 100, and the cover window 10 may be attached to the display panel 100 by an adhesive such as an optically clear adhesive. A touch detecting unit TSU may be positioned between the overcoat layer OC and the cover window 10. The touch detecting unit TSU may be positioned in a different position than shown, for example, between the encapsulation layer TFE and the color filters CF1, CF2, and CF3 as in the embodiment of FIG. 11.

Although embodiments of the disclosure have been described in detail above, the scope of the disclosure is not limited thereto, and various modifications and improvements made by those skilled in the art using the concepts of the disclosure and as defined in the following claims are also possible.

What is claimed is:

1. A light emitting display device, comprising:
a transistor disposed on a substrate;
a pixel electrode electrically connected to the transistor;
a light emitting layer disposed on the pixel electrode;
a common electrode disposed on the light emitting layer;
a low reflection layer disposed on the common electrode; and
a capping layer disposed on the low reflection layer.

2. The light emitting display device of claim 1, wherein
the low reflection layer includes at least one of amorphous silicon and silicon carbide.

3. The light emitting display device of claim 1, wherein
the low reflection layer has a thickness of about 10 nm or less.

4. The light emitting display device of claim 3, wherein
the low reflection layer has a thickness in a range of about 2 nm to about 8 nm.

5. The light emitting display device of claim 4, wherein
the low reflection layer has a thickness in a range of about 4 nm to about 8 nm.

6. The light emitting display device of claim 1, wherein
a lower surface of the low reflection layer contacts an upper surface of the common electrode.

7. The light emitting display device of claim 6, wherein
an upper surface of the low reflection layer contacts a lower surface of the capping layer.

8. The light emitting display device of claim 1, further comprising:
an encapsulation layer disposed on the capping layer.

9. The light emitting display device of claim 8, further comprising:
a color filter disposed on the encapsulation layer.

10. The light emitting display device of claim 9, further comprising:
a pixel defining layer disposed between the pixel electrode and the common electrode, the pixel defining layer having an opening that overlaps the pixel electrode; and
a light blocking layer disposed on the encapsulation layer, the light blocking layer having an opening that overlaps the opening of the pixel defining layer.

11. An electronic device, comprising:
a housing;
a cover window disposed on the housing; and
a display panel disposed between the housing and the cover window,
wherein the display panel comprises:
a transistor disposed on a substrate;
a pixel electrode electrically connected to the transistor;
a light emitting layer disposed on the pixel electrode;
a common electrode disposed on the light emitting layer;
a low reflection layer disposed on the common electrode; and
a capping layer disposed on the low reflection layer.

12. The electronic device of claim 11, wherein
the low reflection layer includes at least one of amorphous silicon and silicon carbide.

13. The electronic device of claim 11, wherein
the low reflection layer has a thickness of about 10 nm or less.

14. The electronic device of claim 13, wherein
the low reflection layer has a thickness in a range of about 2 nm to about 8 nm.

15. The electronic device of claim 14, wherein
the low reflection layer has a thickness in a range of about 4 nm to about 8 nm.

16. The electronic device of claim 11, wherein
a lower surface of the low reflection layer contacts an upper surface of the common electrode.

17. The electronic device of claim 16, wherein
an upper surface of the low reflection layer contacts a lower surface of the capping layer.

18. The electronic device of claim 11, wherein
the display panel further includes an encapsulation layer disposed on the capping layer.

19. The electronic device of claim 18, wherein
the display panel further includes a color filter disposed on the encapsulation layer.

20. The electronic device of claim 19, wherein
the display panel further comprises:
a pixel defining layer disposed between the pixel electrode and the common electrode and having an opening that overlaps the pixel electrode; and
a light blocking layer disposed on the encapsulation layer and having an opening that overlaps the opening of the pixel defining layer.
